(19) United States
(12) Patent Application Publication
(10) Pub. No.: US 2026/0013228 A1
(43) Pub. Date: Jan. 8, 2026

(54) Light-Emitting Substrate and Display Apparatus

(71) Applicants: Hefei BOE Ruisheng Technology Co., Ltd., Hefei, Anhui (CN); BOE TECHNOLOGY GROUP CO., LTD., Chaoyang District, Beijing (CN)

(72) Inventors: Tingwei Han, Beijing (CN); Wenzhuo Tang, Beijing (CN); Zouming Xu, Beijing (CN); Jie Wang, Beijing (CN); Xintao Wu, Beijing (CN); Jiawei Xu, Beijing (CN); Ningyu Luo, Beijing (CN)

(21) Appl. No.: 18/881,689

(22) PCT Filed: May 14, 2024
(86) PCT No.: PCT/CN2024/093208

§ 371 Date: Jan. 6, 2025

(30) Foreign Application Priority Data
Jun. 29, 2023 (CN) 202310798947.0

(51) Int. Cl. H10D 86/40; G02F 1/1335; G02F 1/13357; H10D 86/60

(52) U.S. Cl. CPC H10D 86/441; G02F 1/133603; G02F 1/133606; G02F 1/133608; G02F 1/133612; H10D 86/60

(57) ABSTRACT

A light-emitting substrate includes a substrate, a plurality of signal line groups disposed on the substrate and arranged in a first direction, a plurality of columns of element groups arranged in the first direction, and a plurality of columns of control chips arranged in the first direction. each column of element groups includes a plurality of element groups arranged at intervals in a second direction, a column of element groups is electrically connected to a part of signal lines of a signal line group. Each column of control chips includes a plurality of control chips arranged at intervals in the second direction. A column of control chips is arranged on a side of the column of element groups in the first direction, and is electrically connected to the column of element groups and a part of signal lines of the signal line group.

### CROSS-REFERENCE TO RELATED APPLICATIONS

This application is the United States national phase of International Patent Application No. PCT/CN2024/093208, filed May 14, 2024, and claims priority to Chinese Patent Application No. 202310798947.0, filed Jun. 29, 2023, the disclosures of which are hereby incorporated by reference in their entireties.

### BACKGROUND OF THE INVENTION

### Field of the Invention

The present disclosure relates to the field of display technologies, and in particular, to a light-emitting substrate and a display apparatus.

### Description of Related Art

With the development of light-emitting diode technologies, backlight sources using mini light-emitting diodes (mini-LEDs) or micro-light-emitting diodes (micro-LEDs) have been widely used. The size of the mini-LED is in a range of about 100 μm to 300 μm, and the size of the micro-LED is about less than 100 μm . Due to small size and high brightness, mini-LEDs and micro-LEDs, when applied to a backlight module, may make fine adjustments to the backlight, so as to realize high dynamic range (HDR) display, thereby winning more and more attention.

### SUMMARY OF THE INVENTION

In an aspect, a light-emitting substrate is provided. The light-emitting substrate includes a substrate, a plurality of signal line groups, a plurality of columns of element groups and a plurality of columns of control chips. The plurality of signal line groups are disposed on the substrate and arranged in a first direction. Each signal line group includes a plurality of signal lines arranged in the first direction. The plurality of columns of element groups are arranged in the first direction, each column of element groups includes a plurality of element groups arranged at intervals in a second direction, a column of element groups is electrically connected to a part of signal lines of a signal line group, and each element group includes a plurality of light-emitting elements arranged at intervals in the first direction and electrically connected in sequence. The plurality of columns of control chips are arranged in the first direction, each column of control chips includes a plurality of control chips arranged at intervals in the second direction, a column of control chips is arranged on a side of the column of element groups in the first direction and is electrically connected to the column of element groups and a part of signal lines of the signal line group. The first direction intersects the second direction.

In some embodiments, the plurality of light-emitting elements of the element group include a first light-emitting element and at least one second light-emitting element; the first light-emitting element is located at an end of the element group in the first direction. The signal line group includes a ground line and a first voltage signal line, the ground line is located between the first light-emitting element and the at least one second light-emitting element, and the first voltage signal line is located on a side of the at least one second light-emitting element away from the first light-emitting element. The control chip is disposed on a side of the first light-emitting element in the second direction.

In some embodiments, the light-emitting substrate further includes a first bridge portion, wherein the plurality of light-emitting elements of the element group include a plurality of second light-emitting element, the first bridge portion is configured to connect the first light-emitting element and a second light-emitting element that is closest to the first light-emitting element.

In some embodiments, the element group includes a plurality of second light-emitting elements. The signal line group further includes a first connection line, the first connection line is disposed between two adjacent second light-emitting elements and is configured to connect the two adjacent second light-emitting elements. The light-emitting substrate further includes a first connection pattern electrically connected to the second light-emitting element that is closest to the first light-emitting element and electrically connected to the first bridge portion. A dimension of the connection pattern in the second direction is greater than a dimension of the connection line in the second direction.

In some embodiments, a resistivity of the first bridge portion is less than a resistivity of the first connection line.

In some embodiments, the signal line group further includes a second connection pattern electrically connected to the first light-emitting element and the first bridge portion. A dimension of the second connection pattern in the second direction is greater than a dimension of the first connection line in the second direction.

In some embodiments, the second connection line is located on a side of the first light-emitting element in the second direction or located between the first light-emitting element and the ground line.

In some embodiments, the ground line includes a first main portion and a plurality of first protruding portions. The first main portion extends in the second direction and is located between the first light-emitting element and the at least one second light-emitting element. The plurality of first protruding portions are located on a side of the first main portion proximate to the at least one second light-emitting element and connected to the first main portion. A first protruding portion extends in the first direction and is located between two adjacent element groups in the second direction.

In some embodiments, at least one of all first voltage signal lines included in the plurality of signal line groups is a first target signal line, and the first target signal line includes a second main portion and a plurality of second protruding portions. The second main portion extends in the second direction and is located on a side of the at least one second light-emitting element away from the first light-emitting element. The plurality of second protruding portions are located on a side of the second main portion proximate to the ground line and connected to the second main portion; a second protruding portion extends in the first direction and is located between the two adjacent element groups in the second direction.

In some embodiments, at least one of all first voltage signal lines included in the plurality of signal line groups is a second target signal line, and the second target signal line includes a plurality of second protruding portion. The plurality of second protruding portions are arranged at intervals in the second direction; each second protruding portion is connected to a corresponding element group, and the second protrusion is located on a side of the element group in the second direction. The light-emitting substrate further includes a plurality of second bridge portions, and a second bridge portion is configured to connect two second protruding portions adjacent in the second direction.

In some embodiments, among the first voltage signal lines included in the plurality of signal line groups, an outermost first voltage signal line in the first direction is the second target signal line, and the second target signal line is adjacent to a frame area of the light-emitting substrate.

In some embodiments, a first protruding portion and a second protruding portion are arranged between two adjacent element groups in the second direction, and the first protruding portion and the second protruding portion are arranged side by side in the first direction. In some embodiments, the light-emitting substrate includes a first connection pattern electrically connected to a second light-emitting element that is closest to the first light-emitting element, and located between the ground line and the second light-emitting element that is closest to the first light-emitting element.

In some embodiments, a first protruding portion and a second protruding portion are arranged between two adjacent element groups in the second direction, the first protruding portion and the second protruding portion are arranged side by side in the second direction.

In some embodiments, the light-emitting substrate further comprises a first connection pattern electrically connected to a second light-emitting element that is closest to the first light-emitting element and located on a side of the second light emitting element that is closest to the first light emitting element along the second direction.

In some embodiments, the first connection pattern and the second protruding portion of the light-emitting substrate are arranged side by side in the first direction, and a dimension of the first protruding portion in the first direction is greater than a dimension of a second protruding portion in the first direction.

In some embodiments, a dimension of the first main portion in the first direction is in a range of 1.9 mm to 2.1 mm, and a dimension of the second main portion in the first direction is in a range of 3.4 mm to 3.7 mm.

In some embodiments, the signal line group further includes an address signal line, a power signal line, and a feedback signal line. In the first direction, the address signal line, the power signal line, the ground line, the feedback signal line and the first voltage signal line are arranged in sequence. A portion of the address signal line and a portion of the power signal line are located between the first light-emitting element and the at least one second light-emitting element, and the feedback signal line is located on a side of the ground line away from the control chip and extends along a border of the ground line away from the control chip.

In some embodiments, the light-emitting substrate has a device area and a bonding area arranged side by side in the second direction, and light-emitting elements included in the plurality of element groups are arranged in the device area. The light-emitting substrate further includes a first border, a second border and bonding pins. In a signal line group closest to the first border, a ground line closest to the first border is closer to the first border than a first voltage signal line closest to the first border, and a distance between the first border and the signal line group is in a range of 2.0 mm to 2.3 mm. The first border and the second border are opposite to each other in the first direction, in a signal line group closest to the second border, a first voltage signal line closest to the second border is closer to the second border than a ground line closest to the second border, and a distance between the second border and the signal line group is in a range of 2.0 mm to 2.3 mm. In the second direction, a minimum distance between the bonding pins and the signal line group is in a range of 1.3 mm to 1.6 mm.

In some embodiments, the signal line group includes a ground line and a first voltage signal line; the plurality of light-emitting elements of the element group are arranged between the ground line and the first voltage signal line.

In some embodiments, the light-emitting substrate further includes second connection lines. A second connection line being located between two adjacent light-emitting elements of the element group and configured to connect the two adjacent light-emitting elements. A dimension of the second connection line in the second direction is greater than a dimension of the light-emitting element in the second direction, and a distance between two adjacent second connection lines in the second direction is less than the dimension of the second connection line in the second direction.

In some embodiments, the ground line includes a third main portion and at least one third protruding portion. The third main portion extends in the second direction. The at least one third protruding portion is located on a side of the third main portion proximate to the first voltage signal line and connected to the third main portion; a third protruding portion extends in the first direction and is located between two adjacent element groups in the second direction. The first voltage signal line includes a fourth main portion and at least one fourth protruding portion. The fourth main portion extends in the second direction. The at least one fourth protruding portion is located on a side of the fourth main portion proximate to the ground line and connected to the fourth main portion; a fourth protruding portion extends in the first direction and is located between another two adjacent element groups in the second direction. The light-emitting substrate further includes a third bridge portion and a fourth bridge portion. An end of third bridging portion is electrically connected to an end of the third protruding portion away from the third main portion, and another end of third bridging portion is electrically connected to a ground line of an adjacent signal line group. An end of the fourth bridge portion is electrically connected to an end of the fourth protruding portion away from the fourth main portion, and another end of the fourth protruding portion is electrically connected to a first voltage signal line of another adjacent signal line group.

In some embodiments, at least one element group is arranged between a third protruding portion and a fourth protruding portion that are adjacent to each other in the second direction; in the second direction, a dimension of the third protruding portion is less than the dimension of the second connection line, and a dimension of the fourth protruding portion is less than the dimension of the second connection line.

In some embodiments, the light-emitting substrate has a device area and a bonding area arranged side by side in the second direction, and the light-emitting elements of the plurality of element groups are arranged in the device area. The light-emitting substrate further includes a first voltage signal pin and a fifth bridge portion. The first voltage signal pin is arranged in the bonding area. The fifth bridge portion is configured to connect the first voltage signal line and the first voltage signal pin.

In some embodiments, the signal line group further includes an address signal line, a data signal line and a power signal line; in the first direction, the first voltage signal line, the power signal line, the data signal line, the address signal line and the ground line are arranged in sequence.

In another aspect, a display apparatus is provided. The display apparatus includes a display panel and the light-emitting substrate according to any one of the above embodiments. The light-emitting substrate is located on a non-display surface of the display panel.

### BRIEF DESCRIPTION OF THE DRAWINGS

In order to describe technical solutions in some embodiments of the present disclosure more clearly, the accompanying drawings to be used in some embodiments of the present disclosure will be introduced briefly; obviously, the accompanying drawings to be described below are merely some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a plan view of a display apparatus, in accordance with some embodiments;

FIG. 2 is a sectional view of a display apparatus, in accordance with yet other embodiments;

FIG. 3 is a structural diagram of a light emitting substrate, in accordance with some embodiments;

FIG. 4 is an enlarged partial view of the A region in FIG. 3;

FIG. 5 is a sectional view along the line C1-C1, the line C2-C2 and the line C3-C3 in FIG. 4;

FIG. 6 is an enlarged partial view of the B region in FIG. 3;

FIG. 7 is a structural diagram of a control chip, in accordance with some embodiments;

FIG. 8 is a structural diagram of another light-emitting substrate, in accordance with some embodiments;

FIG. 9 is a structural diagram of yet another light-emitting substrate, in accordance with some embodiments;

FIG. 10 is an enlarged partial view of the D region in FIG. 9;

FIG. 11 is a structural diagram of yet another light-emitting substrate, in accordance with some embodiments;

FIG. 12 is a structural diagram of yet another light-emitting substrate, in accordance with some embodiments; and

FIG. 13 is an enlarged partial view of the E region in FIG. 12.

### DESCRIPTION OF THE INVENTION

The technical solutions in some embodiments of the present disclosure will be described clearly and completely with reference to the accompanying drawings; obviously, the described embodiments are merely some but not all embodiments of the present disclosure. All other embodiments obtained by a person having ordinary skill in the art based on the embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “including, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

The terms “first” and “second” are used for descriptive purposes only, and are not to be construed as indicating or implying a relative importance or implicitly indicating a number of indicated technical features. Thus, a feature defined with “first” or “second” may explicitly or implicitly include one or more of the features. In the description of the embodiments of the present disclosure, the term “multiple”, “a plurality of” or “the plurality of” means two or more unless otherwise specified.

Some embodiments may be described using the term “connected” and its derivatives. The term “connected” should be understood in a broad sense; for example, the term “connected” may represent a fixed connection, or a detachable connection, or a one-piece connection; alternatively, the term “connected” may represent a direct connection, or an indirect connection through an intermediate medium.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

As used herein, the term “if” is, optionally, construed as “when” or “in a case where” or “in response to determining that” or “in response to detecting,” depending on the context. Similarly, depending on the context, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event].”

The use of the phrase “applicable to” or “configured to” herein means an open and inclusive expression, which does not exclude devices that are applicable to or configured to perform additional tasks or steps.

In addition, the use of the phrase “based on” or “according to” is meant to be open and inclusive, since a process, step, calculation or other action that is “based on” or “according to” one or more of the stated conditions or values may, in practice, be based on or according to additional conditions or values exceeding those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, a difference between two equals being less than or equal to 5% of either of the two equals.

It will be understood that, in a case where a layer or an element is referred to as being on another layer or a substrate, it may be that the layer or the element is directly on the another layer or the substrate, or there may be a middle layer between the layer or the element and the another layer or the substrate.

Exemplary embodiments are described herein with reference to sectional views and/or plan views that are schematic illustrations of idealized embodiments. In the drawings, thicknesses of layers and sizes of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature being curved. Therefore, the regions shown in the accompanying drawings are schematic in nature, and their shapes are not intended to show actual shapes of the regions in a device, and are not intended to limit the scope of the exemplary embodiments.

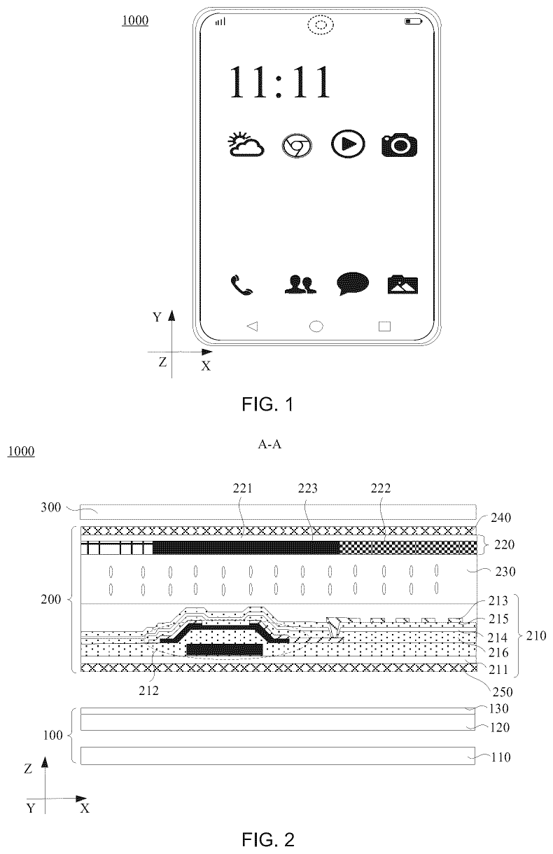

Referring to FIG. 1, some embodiments of the present disclosure provide a display apparatus 1000, and the display apparatus 1000 may be any apparatus that displays an image whether in motion (e.g., a video) or stationary (e.g., a still image), and whether textual or graphical.

For example, the display apparatus 1000 may be a mobile phone, a wireless apparatus, a personal digital assistant (PDA), a wearable device, an augmented reality (AR) device, a virtual reality (VR) device, a hand-held or portable computer, a GPS receiver/navigator, a camera, an MP4 video player, a video camera, a game console, a watch, a clock, a calculator, a television monitor, a flat panel display, a computer monitor, an automobile display (e.g., an odometer display), a cockpit controller and/or display, a display of camera views (e.g., a display of a rear-view camera in a vehicle), an electronic photo, an electronic billboard or sign, a projector, or a packaging and aesthetic structure (e.g., a display for displaying an image of a piece of jewelry).

In some embodiments, the display apparatus 1000 may be in a shape of rectangle, circle, or any other shape, which is not specifically limited in the embodiments of the present disclosure. Some embodiments of the present disclosure are schematically described below by taking a rectangular display apparatus as an example, but the implementations of the present disclosure are not limited thereto, and any other display apparatuses may also be considered as long as the same technical concept is applied.

In some embodiments, the display apparatus 1000 may be a liquid crystal display (LCD) apparatus. Referring to FIG. 2, the display apparatus 1000 may include a backlight module 100, a display panel 200 and a glass cover plate 300. The display panel 200 includes a display surface and a non-display surface. The display surface refers to a surface of the display panel 200 for displaying a picture, i.e., an upper surface of the display panel 200 in FIG. 2, and the non-display surface refers to the other surface opposite to the display surface. The backlight module 100 is disposed on the non-display surface of the display panel 200, i.e., a lower surface of the display panel 200 in FIG. 2, and the backlight module 100 is used for providing a light source for the display panel 200. The glass cover plate 300 is disposed on the display surface of the display panel 200, so as to cover and protect the display panel 200.

In some embodiments, referring to FIG. 2, in the case where the display apparatus 1000 may be a liquid crystal display apparatus, the display panel 200 may be a liquid crystal display panel, the display panel 200 includes an array substrate 210, an opposite substrate 220, and a liquid crystal layer 230 disposed between the array substrate 210 and the opposite substrate 220. The array substrate 210 is provided with thin film transistors (TFTs) and pixel electrodes 213 that are located on a first substrate 211 therein. The thin film transistor 212 includes an active layer, a source, a drain, a gate and a gate insulating layer, the source and the drain are both in contact with the active layer, and the pixel electrode 213 is electrically connected to the drain of the thin film transistor 212.

In some embodiments, as shown in FIG. 2, the array substrate 210 further includes a common electrode 214 disposed on the first substrate 211. The pixel electrode 213 and the common electrode 214 may be disposed in different layers; in this case, as shown in FIG. 2, a first insulating layer 215 is provided between the pixel electrode 213 and the common electrode 214. In a case where the common electrode 214 is disposed between the thin film transistor 212 and the pixel electrode 213, as shown in FIG. 2, a second insulating layer 216 is provided between the common electrode 214 and the thin film transistor 212.

The pixel electrode 213 and the common electrode 214 may also be disposed in the same layer (not shown in the figures); in this case, the pixel electrode 213 and the common electrode 214 are each of a comb-tooth structure including a plurality of stripe-shaped sub-electrodes. In some other embodiments, the common electrode 214 may be disposed in the opposite substrate 220.

As shown in FIG. 2, the opposite substrate 220 may include a color filter layer 222 disposed on a second substrate 221, in which case the opposite substrate 220 may also be referred to as a color filter (CF) substrate. In a case where the backlight module 100 is used to emit white light, the color filter layer 222 includes at least a red photoresist unit, a green photoresist unit and a blue photoresist unit, and the red photoresist unit, the green photoresist unit and the blue photoresist unit are directly opposite to the sub-pixels in the display panel 200, respectively. The opposite substrate 220 further includes black matrix patterns 223 disposed on the second substrate 221, and the black matrix patterns 223 are used for separating the red photoresist units, the green photoresist units and the blue photoresist units.

As shown in FIG. 2, the display panel 200 may further include a first polarizer 240 disposed on a side of the opposite substrate 220 away from the liquid crystal layer 230, and a second polarizer 250 disposed on a side of the array substrate 210 away from the liquid crystal layer 230. In addition, the display panel 200 may further include other film layers or structures, which are not listed one by one in the embodiments of the present disclosure.

In some embodiments, the backlight module 100 includes a light-emitting substrate 110. The light-emitting substrate 110 may directly emit white light, which is directed to the display panel 200 after a light uniformizing treatment. Alternatively, the light-emitting substrate 110 may emit light of another color, and then the light of another color is directed to the display panel 200 after color conversion and a light uniformizing treatment. The backlight module 100 further includes an optical film 120, and the optical film 120 may include a diffuser plate and/or an optical brightness enhancement film, which is not limited in the embodiments of the present disclosure. The diffusion plate has a scattering and diffusion effect, and is capable of further mixing the above-mentioned white light uniformly; and the optical brightness enhancement film is capable of improving the light extraction efficiency of the backlight module 100. In addition, the backlight module 100 may further include other film layers or structures, which are not listed one by one in the embodiments of the present disclosure.

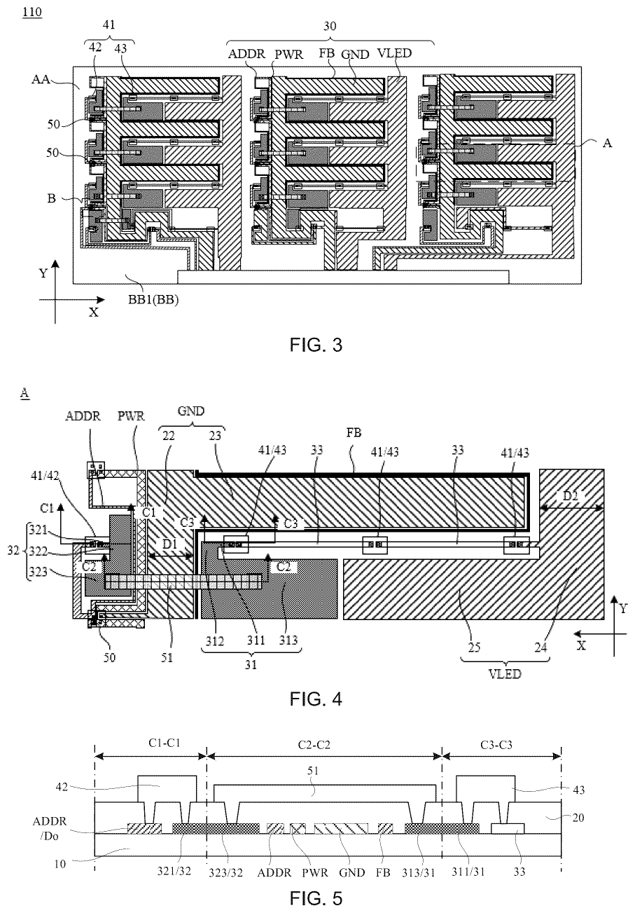

In some embodiments, referring to FIGS. 3 and 4, the light-emitting substrate 110 includes a substrate 10, a plurality of signal line groups 30, a plurality of columns of element groups 40, and a plurality of columns of control chips 50. FIG. 3 is a schematic structural diagram of the light-emitting substrate in which first protruding portions and second protruding portions are arranged side by side in a first direction; FIG. 4 is a diagram showing a connection relationship between an element group and a signal line group and control chip.

The light-emitting substrate 110 may include a device area AA and a frame area BB. The device area AA is used to provide a plurality of columns of element groups 40 and a plurality of columns of control chips 50. In addition, at least part of the plurality of signal lines included in the signal line group 30 are disposed in the device area AA. The device area AA is also used to emit light. The frame area BB is located at least on one side of the device area AA. For example, the frame area BB surrounds the device area AA. The frame area BB is used to arrange signal lines. For example, the frame area BB includes a bonding area BB1 located on a side of the device area AA in a second direction Y. The bonding area BB1 may be used to provide a fan-out line of the signal line group 30 and bonding pins.

The substrate 10 may be rigid substrate or flexible substrate. For example, the material of the substrate 10 may include any one of glass, quartz, plastic, an FR-4 material, a resin, polyimide and polymethyl methacrylate (PMMA), which is not limited in the embodiments of the present disclosure.

A plurality of signal line groups 30 are disposed on the substrate 10 and arranged in the first direction X. Each signal line group 30 includes a plurality of signal lines arranged in the first direction X. Each signal line group 30 is electrically connected to a column of element groups 40 and a column of control chips 50, and is configured to control a column of control chips 50 and a column of element groups 40, and control the element groups 40 to emit light through the control chips 50.

For example, as shown in FIGS. 3 and 4, the plurality of signal lines in the signal line group 30 may include a first voltage signal line VLED, a ground line GND, an address signal line ADDR, a power signal line PWR, and a feedback signal line FB. Of course, the signal line group 30 may further include other signal lines, such as connection lines for connecting the element group 40 and the control chip 50 (described below), which are not listed here one by one.

In some embodiments, referring to FIG. 5, FIG. 5 is a sectional view of a light-emitting substrate 110, the light-emitting substrate 110 may be of a single metal layer structure. In other words, the light-emitting substrate 110 only includes one conductive metal layer. In this case, the plurality of signal lines of the signal line group 30 are made of the same material and are arranged in the same layer. Based on this, the plurality of signal line groups 30 may be formed by a single patterning process, which is conducive to simplifying the manufacturing process of the light-emitting substrate 110, thereby reducing the manufacturing cost of the light-emitting substrate 110. For example, the light-emitting substrate 110 may further include an insulating layer 20, and the insulating layer 20 is disposed on a side of the signal line group 30 away from the substrate 10. The insulating layer 20 can cover the conductive layer where the signal line groups 30 are located to play a role of electrical isolation. Of course, the light-emitting substrate 110 may further include other layers, which will not be listed one by one in the embodiments of the present disclosure.

The plurality of columns of element groups 40 are arranged in the first direction X, each column of element groups 40 includes a plurality of element groups 40 arranged at intervals in the second direction Y, a column of element groups 40 is electrically connected to part of the signal lines of a signal line group 30, and each element group 40 includes a plurality of light-emitting elements 41 arranged at intervals in the first direction X and electrically connected in sequence.

The plurality of element groups 40 in each column of element groups 40 are connected to a corresponding signal line group 30, so that the number of signal line groups 30 is equal to the number of columns of the element groups 40. The plurality of light-emitting elements 41 in each element group 40 are arranged in the first direction X. In a case where the arrangement quantity and arrangement density of the light-emitting elements 41 remain unchanged, the space occupied by the element group 40 in the first direction X may be increased to the maximum extent, thereby reducing the number of columns of the element groups 40 and reducing the number of signal line groups 30.

For example, as shown in FIG. 4, each element group 40 is electrically connected to the first voltage signal line VLED in the signal line group 30, and the element group 40 is electrically connected to the control chip 50. Each element group 40 may include, for example, two, four, six or eight light-emitting elements 41, which is not specifically limited in the embodiments of the present disclosure. The following embodiments of the present disclosure are described by taking an example in which each element group 40 includes four light-emitting elements 41.

For example, if an element group 40 includes four light-emitting elements 41 arranged in a manner of two rows and two columns (2*2), 2N columns of element groups 40 may be arranged on the substrate 10. Assuming that the size of the substrate 10 remains unchanged and the arrangement density of the light-emitting elements 41 remains unchanged, an element group 40 includes four light-emitting elements 41 arranged in the first direction X (1*4), then N columns of element groups 40 may be arranged on the substrate 10. That is to say, through the arrangement manner of the element groups 40 in the embodiments of the present disclosure, the number of columns of the element groups 40 may be reduced to half of the original number. Based on this, the number of signal line groups 30 may be reduced to half of the original number. Thus, it is beneficial to reducing the number of fan-out lines, thereby reducing the width of the frame area BB, especially reducing the width of the bonding area BB1. Moreover, in the case where the area of the substrate 110 remains unchanged and the arrangement density of the light-emitting elements 41 remains unchanged, the wiring space of the signal line group 30 may be greatly improved due to the reduction in the number of signal line groups 30, which is beneficial to increase the width of the plurality of signal lines included in the signal line group 30, thereby reducing the resistance of the plurality of signal lines included in the signal line group 30. Thus, the thickness of the signal lines included in the signal line group 30 may be reduced, so that the amount of etching solution used in the fabricate process of the signal line group 30 may be reduced.

It will be understood that the fabricate process of the signal line group 30 may include forming a continuous whole metal layer on the substrate 10 by magnetron sputtering, and the fabricate process of the above-mentioned continuous whole metal layer is not limited thereto. For example, it may also be fabricated by evaporation, chemical vapor deposition or material vapor deposition, as long as a continuous whole metal layer may be formed. Then, a mask layer is formed on the continuous whole metal layer. The process of forming the mask layer may include coating, exposure and development, etc. Then, the continuous whole metal layer is etched with an etching solution to obtain the signal line group 30. Finally, the mask layer is removed by an etching process. Based on the above-mentioned fabricate process of the signal line group 30, the thickness of the signal lines included in the signal line group 30 may be reduced, which is beneficial to reducing the thickness of the formed continuous whole metal layer, thereby reducing the amount of etching solution used in the subsequent etching process. The material of the whole metal layer may be copper, for example.

In some embodiments, in terms of the type of the light-emitting element 41, the light-emitting element 41 may be an LED having a quantum well junction, an LED having a columnar structure, an LED having a double heterojunction, or the like. From the perspective of the size of the light-emitting element 41, the light-emitting element 41 may be of a structure whose size is miniaturized to the order of hundreds of microns. For example, the area of the light-emitting region of the light-emitting element 41 may be less than 1 mm², or the area of the light-emitting region of the light-emitting element 41 may be less than 10000 μm², the area of the light-emitting region of the light-emitting element 41 may be less than 3000 μm², the area of the light-emitting region of the light-emitting element 41 may be less than 700 μm², or the area of the light-emitting region of the light-emitting element 41 may be less than 200 μm², and the embodiments of the present disclosure are not limited thereto; alternatively, the light-emitting element 41 may be a light-emitting element of other structures, as long as the same technical concept as that of the present disclosure is applied.

The light-emitting element 41 may include a P electrode (positive electrode) and an N electrode (negative electrode). The P electrode of the light-emitting element 41 may be electrically connected to the first voltage signal line VLED, and the N electrode may be electrically connected to the control chip 50. Of the two light-emitting elements 41 connected to each other in an element group 40, the N electrode of one light-emitting element 41 (the light-emitting element 41 closer to the first voltage signal line VLED) is electrically connected to the P electrode of the other light-emitting element 41. That is, the two light-emitting elements 41 are connected in series.

The plurality of columns of control chips 50 are arranged in the first direction X, and each column of control chips 50 includes a plurality of control chips 50 arranged at intervals in the second direction Y. A column of control chips 50 is disposed on a side of a column of element groups 40, and is electrically connected to the column of element groups 40 and a part of signal lines in a signal line group 30.

A control chip 50 may control one or more element groups 40, which is not specifically limited in the embodiments of the present disclosure. The following embodiments of the present disclosure will be described by taking an example in which the control chip 50 controls one element group 40 or four element groups 40. It can be understood that the control chip 50 may also be used to control other numbers of element groups 40 as long as the same technical ideas as those of the present disclosure are applied.

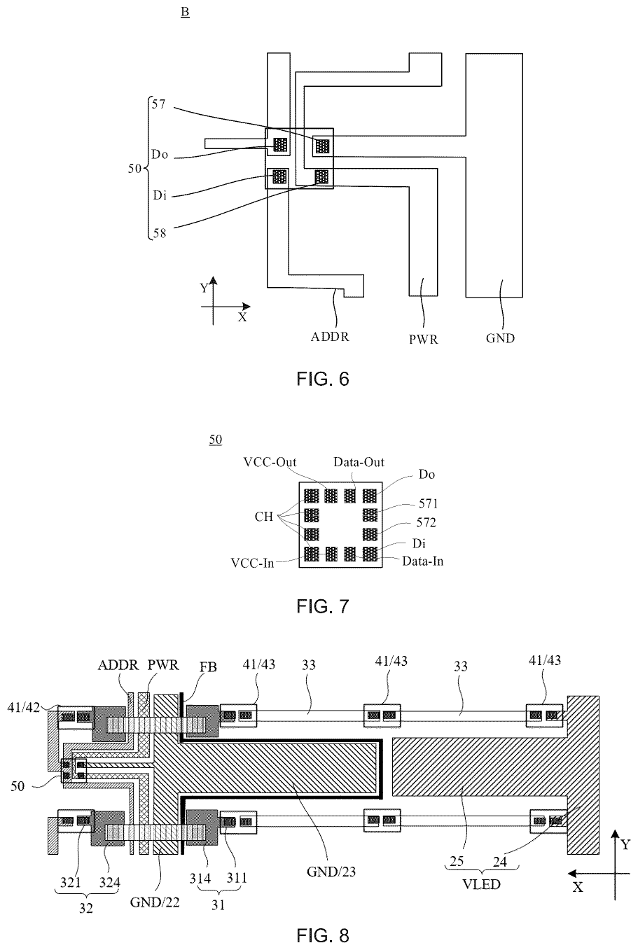

In some embodiments, in a case where the control chip 50 may be used to control one element group 40, as shown in FIG. 6, the control chip 50 includes a signal input pin Di (an input pin of an addressing signal), a signal output pin Do, a ground pin 57, and a power pin 58. The plurality of control chips 50 in a column of control chips 50 are sequentially cascaded (not shown in figures), and in two control chips 50 that are cascaded, a signal output pin Do of a former control chip 50 is electrically connected to a signal input pin Di of a latter control chip 50. The ground pin 57 is electrically connected to the ground line GND, and the power pin 58 is electrically connected to the power signal line PWR. The signal output pin Do is further electrically connected to the plurality of light-emitting elements 41 in the element group 40. For example, the signal output pin Do is electrically connected to the N electrode of the light-emitting element 41, and The P electrode of the light-emitting device 41 is electrically connected to the first voltage signal line VLED.

For example, in the case where a control chip 50 is used to control four element groups 40, as shown in FIG. 7, the control chip 50 may include a signal input pin Di, a signal output pin Do, a power signal input pin VCC-In, a power signal output pin VCC-Out, a data signal input pin Data-In, a data signal output pin Data-Out, a first ground pin 571, a second ground pin 572 and four output pins CH, and the four output pins CH are respectively electrically connected to the four element groups 40. The first ground pin 571 and the second ground pin 572 are both electrically connected to the ground line GND. In the two cascaded control chips 50, the signal output pin Do of the former control chip 50 is electrically connected to the signal input pin Di of the latter control chip 50, and the power signal output pin VCC-Out of the former control chip 50 is electrically connected to the power signal input pin VCC-In of the latter control chip through the power signal line PWR. The signal line group 30 further includes data connection lines, and the data signal output pin Data-Out of the former control chip 50 is electrically connected to the data signal input pin Data-In of the latter control chip 50 through the data connection line.

It can be understood that the structures of the above two types of the control chip 50 are only exemplary, and the embodiments of the present disclosure are not limited thereto, as long as the same technical concept as that of the present disclosure is adopted.

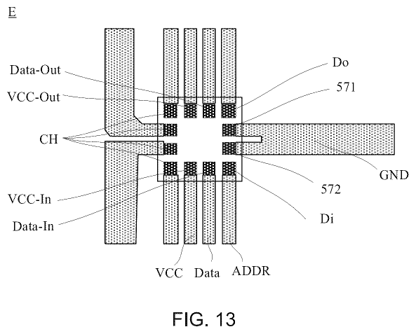

In some embodiments, the signal line group 30 includes a ground line GND and a first voltage signal line VLED. The first voltage signal line VLED is disposed on a side of the plurality of light-emitting elements 41 in the element group 40 in the first direction X; the ground line GND may be arranged between two adjacent light-emitting elements 41 among the plurality of light-emitting elements 41 (as shown in FIGS. 3 and 4), or the ground line GND may be arranged on the other side of the plurality of light-emitting elements 41 in the element group 40 in the first direction X (as shown in FIGS. 12 and 13).

In a case where the ground line GND is disposed between two adjacent light-emitting elements 41 among the plurality of light-emitting elements 41, referring to FIG. 4, the plurality of light-emitting elements 41 of the element group 40 include a first light-emitting element 42 and at least one second light-emitting element 43. The first light-emitting element 42 is located at an end of the element group 40 in the first direction X. The following embodiments of the present disclosure are described by taking an example that the element group 40 includes four light-emitting elements 41 and the first light-emitting element 42 is the leftmost one among the four light-emitting elements 41. In this way, the four light-emitting elements 41 include a first light-emitting element 42 located at the leftmost side and three second light-emitting elements 43 located at the right side of the first light-emitting element 42.

As shown in FIG. 4, the signal line group 30 includes a ground line GND and a first voltage signal line VLED. The first voltage signal line VLED is used to provide a power supply voltage for the light-emitting elements 41, and the first voltage signal line VLED is arranged on a side of the at least one second light-emitting element 43 away from the first light-emitting element 42. In other words, the first voltage signal line VLED is arranged on the right side of the plurality of light-emitting elements 41 included in the element group 40. The ground line GND is located between the first light-emitting element 42 and the at least one second light-emitting element 43 (all the second light-emitting elements 43), which is beneficial for the ground line GND and the first voltage signal line VLED to utilize the gap between two adjacent element groups 40 (referring to the description below) to further increase the area of the ground line GND and the first voltage signal line VLED, reduce the resistance of the ground line GND and the first voltage signal line VLED, and reduce the thickness of the ground line GND and the first voltage signal line VLED, so that layout of plurality of signal lines of the signal line group 30 may be optimized to improve the space utilization rate of the substrate 10.

As shown in FIG. 4, in an example in which a control chip 50 controls an element group 40, the control chip 50 may be arranged on a side of the first light-emitting element 42 in the second direction Y. In this case, the control chip 50 is also located on a side of the ground line GND proximate to the first light-emitting element 42. For example, the control chip 50 is disposed at the lower side of the first light-emitting element 42.

As shown in FIG. 4, the ground line GND is disposed between the first light-emitting element 42 and the second light-emitting element 43, and the first light-emitting element 42 and the second light-emitting element 43 cannot be directly electrically connected via a connection line disposed on the same layer as the signal line group 30. Therefore, the light-emitting substrate 110 further includes a first bridge portion 51 configured to connect the first light-emitting element 42 and the second light-emitting element 43 closest to the first light-emitting element 42 to enable the plurality of light-emitting elements 41 to be sequentially connected.

For example, the first bridge portion 51 may be a chip resistor or a jumper resistor. The jumper resistor, also known as a zero-ohm resistor, is a special-purpose resistor with a very small resistance value. An automatic placement machine or an automatic insertion machine may be used to provide a jumper resistor between two points in the wiring substrate that cannot be directly connected by a line to achieve electrical connection between the two points. Moreover, it is helpful to reduce the resistance value between the first light-emitting element 42 and the second light-emitting element 43.

In some embodiments, as shown in FIG. 4, the element group 40 includes a plurality of second light-emitting elements 43. The signal line group 30 further includes first connection line(s) 33. The first connection line 33 is disposed between two adjacent second light-emitting elements 43, and the first connection line 33 is configured to connect two adjacent second light-emitting elements 43.

For example, the resistivity of the first bridge portion 51 is less than the resistivity of the first connection line 33, which is helpful to reduce the resistance value between the first light-emitting element 42 and the second light-emitting element 43.

In some embodiments, as shown in FIG. 4, the first connection line 33 extend in the first direction X, and the plurality of first connection lines 33 electrically connected to the plurality of second light-emitting elements 43 of the same element group 40 are arranged substantially in the first direction X. In this way, the space occupied by the plurality of first connection lines 33 in the second direction Y may be minimized, thereby improving the utilization rate of the wiring space on the substrate 10.

With continued reference to FIG. 4, the light-emitting substrate 110 further includes a first connection pattern 31 and a second connection pattern 32. The first connection pattern 31 is electrically connected to the second light-emitting element 43 closest to the first light-emitting element 42, and the second connection pattern 32 is electrically connected to the first light-emitting element 42. Two ends of the first bridge portion 51 are electrically connected to the first connection pattern 31 and the second connection pattern 32 respectively. Thus, the second light-emitting element 43 closest to the first light-emitting element 42 is electrically connected to the first light-emitting element 42 via the first connection pattern 31, the first bridge portion 51 and the second connection pattern 32 in sequence.

As shown in FIG. 4, a dimension of the first connection pattern 31 in the second direction Y is greater than a dimension of the first connection line 33 in the second direction Y. Thus, it is beneficial to increase the area of the first connection pattern 31, thereby reducing the difficulty of connecting the first connection pattern 31 to the first bridge portion 51, and it is beneficial to increase the heat dissipation capacity of the first connection pattern 31, thereby avoiding heat accumulation on the first connection pattern 31. As shown in FIG. 4, the first connection pattern 31 may be located at a side of the second light-emitting element 43 in the second direction Y; alternatively, as shown in FIG. 8, the first connection pattern 31 may be located between the second light-emitting element 43 and the ground line GND.

For example, as shown in FIG. 4, in a case where the first connection pattern 31 is located on a side of the second light-emitting element 43 in the second direction Y, the first connection pattern 31 may include a first sub-pattern 311, a second sub-pattern 312, and a third sub-pattern 313. The first sub-pattern 311, the second sub-pattern 312, and the third sub-pattern 313 are arranged side by side in the second direction Y. The first sub-pattern 311 extends in the first direction X, and an end of the first sub-pattern 311 is electrically connected to the second light-emitting element 43 closest to the first light-emitting element 42, and the other end of the first sub-pattern 311 is connected to the second sub-pattern 312. The dimension of the first sub-pattern 311 in the second direction Y may be equal to the dimension of the first connection line 33 in the second direction Y. In this way, the size of the pad on the signal line group 30 electrically connected to each second light-emitting element 43 may be equal, which is beneficial to improving the structural uniformity of the light-emitting substrate 110. The second sub-pattern 312 extends in the second direction Y, and an end of the second sub-pattern 312 is connected to an end of the first sub-pattern 311 proximate to the first light-emitting element 42, and the other end of the second sub-pattern 312 is electrically connected to the third sub-pattern 313. The third sub-pattern 313 may extend in the first direction X, and the dimension of the third sub-pattern 313 in the first direction X is greater than the dimension of the first sub-pattern 311 in the first direction X. The dimension of the third sub-pattern 313 in the second direction Y is greater than the dimension of the first sub-pattern 311 in the second direction Y. The first bridge portion 51 is connected to the third sub-pattern 313 of the first connection pattern 31, the area of the third sub-pattern 313 is increased (compared to the first sub-pattern 311), which facilitates the connection between the third sub-pattern 313 and the first bridge portion 51, and reduces the resistance of the first connection pattern 31. Moreover, the first connection pattern 31 is located on a side of the second light-emitting element 43 in the second direction Y, and in this case, it is possible to provide more signal lines (first protruding portions and second protruding portions) between two adjacent element groups 40 in the second direction Y, which is beneficial to improving the utilization rate of the wiring space of the substrate 10.

For example, as shown in FIG. 8, in a case where the first connection pattern 31 is located between the second light-emitting element 43 and the ground line GND, the first connection pattern 31 may include a first sub-pattern 311 and a fourth sub-pattern 314, and the first sub-pattern 311 and the fourth sub-pattern 314 are arranged side by side in the first direction X. The first sub-pattern 311 extends in the first direction X, and an end of the first sub-pattern 311 is electrically connected to the second light-emitting element 43 closest to the first light-emitting element 42, and the other end of the first sub-pattern 311 is connected to the fourth sub-pattern 314. The dimension of the first sub-pattern 311 in the second direction Y may be equal to the dimension of the first connection line 33 in the second direction Y. In this way, the size of the pad on the signal line group 30 electrically connected to each light-emitting element 41 may be equal, which is beneficial to improving the structural uniformity of the light-emitting substrate 110. The fourth sub-pattern 314 may be in a shape of a rectangle, the dimension of the fourth sub-pattern 314 in the second direction Y is greater than the dimension of the first sub-pattern 311 in the second direction Y. The first bridge portion 51 is connected to the fourth sub-pattern 314 of the first connection pattern 31, and in this case, the area of the fourth sub-pattern 314 (compared to the first connection pattern 31) is increased, which is beneficial for connecting the fourth sub-pattern 314 to the first bridge portion 51. The first connection pattern 31 is located between the second light-emitting element 43 and the ground line GND, which is beneficial to simplify the structure of the first connection pattern 31.

It is understandable that the specific shapes of the above two first connection patterns 31 are only examples, and the embodiments of the present disclosure are not limited thereto, as long as the first connection pattern 31 can connect the second light-emitting element 43 closest to the first light-emitting element 42 to the first bridge portion 51.

In some embodiments, as shown in FIGS. 4 and 8, for similar reasons to the first connection pattern 31, the second connection pattern 32 is electrically connected to the first light-emitting element 42 and the first bridge portion 51, and the dimension of the second connection pattern 32 in the second direction Y is greater than the dimension of the first connection line 33 in the second direction Y, which is beneficial to increase the area of the second connection pattern 32, thereby reducing the difficulty of connection between the second connection pattern 32 and the first bridge portion 51, and reducing the resistance of the second connection pattern 32.

Referring to FIG. 4, the second connection pattern 32 may be located at a side of the first light-emitting element 42 in the second direction Y. Alternatively, referring to FIG. 8, the second connection pattern 32 may be located between the first light-emitting element 42 and the ground line GND.

In the case where the second connection pattern 32 is located on a side of the first light-emitting element 42 in the second direction Y, as shown in FIG. 4, the second connection pattern 32 may include a fifth sub-pattern 321, a sixth sub-pattern 322, and a seventh sub-pattern 323. The fifth sub-pattern 321 extends in the first direction X, and an end of the fifth sub-pattern 321 is electrically connected to the first light-emitting element 42, and the other end of the fifth sub-pattern 321 is connected to the sixth sub-pattern 322. The dimension of the fifth sub-pattern 321 in the second direction Y may be equal to the dimension of the first connection line 33 in the second direction Y. In this way, the size of the pad electrically connected to the first light-emitting element 42 and the size of the pad electrically connected to the second light-emitting element 43 may be equal, which is beneficial to improving the structural uniformity of the light-emitting substrate 110. The sixth sub-pattern 322 extends in the second direction Y. The fifth sub-pattern 321 is connected to the middle of the sixth sub-pattern 322 in the second direction Y. An end (lower end) of the sixth sub-pattern 322 proximate to the bridge portion 51 in the second direction Y is connected to the seventh sub-pattern 323. The seventh sub-pattern 323 is substantially in a shape of a rectangle, and the dimension of the seventh sub-pattern 323 in the second direction Y is greater than the dimension of the fifth sub-pattern 321 in the second direction Y. The first bridge portion 51 is connected to the seventh sub-pattern 323 of the second connection pattern 32, and in this case, the area of the seventh sub-pattern 323 is increased (compared with the fifth sub-pattern 321), which facilitates the connection between the seventh sub-pattern 323 and the first bridge portion 51, and helps improve the utilization rate of the wiring space of the substrate 10.

In the case where the second connection pattern 32 may be located between the first light-emitting element 42 and the ground line GND, as shown in FIG. 8, the second connection pattern 32 may include a fifth sub-pattern 321 and an eighth sub-pattern 324, and the fifth sub-pattern 321 and the eighth sub-pattern 324 are arranged side by side in the first direction X. The fifth sub-pattern 321 extends in the first direction X, and an end of the fifth sub-pattern 321 is electrically connected to the first light-emitting element 42, and the other end of the fifth sub-pattern 321 is connected to the eighth sub-pattern 324. The dimension of the fifth sub-pattern 321 in the second direction Y may be equal to the dimension of the first connecting line 33 in the second direction Y, which is beneficial to improving the structural uniformity of the light-emitting substrate 110. The eighth sub-pattern 324 may be in a shape of a rectangle, and a dimension of the eighth sub-pattern 324 in the second direction Y is greater than a dimension of the fifth sub-pattern 321 in the second direction Y. The first bridge portion 51 is connected to the eighth sub-pattern 324 of the second connection pattern 32, and in this case, the area of the eighth sub-pattern 324 (compared to the fifth sub-pattern 321) is increased, which is beneficial for the connection between the eighth sub-pattern 324 and the first bridge portion 51. The second connection pattern 32 is located between the first light-emitting element 42 and the ground line GND, which is beneficial to simplify the structure of the second connection pattern 32.

In the embodiments of the present disclosure, it is possible to route the line between two adjacent element groups 40 in the second direction Y, which improves the utilization of the wiring space on the substrate 10 and reduce the resistance of the corresponding signal line.

In some embodiments, referring to FIG. 10, the ground line 13 includes a main portion 22 and a plurality of protruding portions 23. The first main portion 22 extends in the second direction Y and is located between the first light-emitting element 42 and the at least one second light-emitting element 43 (all the second light-emitting elements 43). The plurality of first protruding portions 23 are located on a side of the first main portion 22 proximate to the at least one second light-emitting element 43 and are connected to the first main portion 23. The first main portion 22 is also used to connect the plurality of first protruding portions 23 into a whole. The first protruding portions 23 each extend in the first direction and is located between two adjacent element groups 40 in the second direction Y. In the embodiments of the present disclosure, the first protruding portions 23 are arranged by utilizing the gap between two adjacent element groups 40, which may increase the area of the ground line GND without increasing the area of the substrate 10, thereby reducing the resistance of the ground line GND. Thus, it is beneficial to reducing the dimension of the first main portion 22 in the first direction X and reducing the dimension of the signal line group 30 in the first direction X. Moreover, it is helpful to reduce the thickness of the ground line GND, reduce the usage of etching solution in the process of forming the ground trace GND, so as to reduce the fabricate difficulty and cost of the ground line GND.

In some embodiments, as shown in FIG. 4, a dimension of the first main portion 22 in the first direction X is denoted as D1, and D1 is in a range of 1.9 mm to 2.1 mm, which is beneficial to increase the area of the first main portion 22, thereby reducing the resistance and thickness of the ground line GND. For example, the dimension D1 of the first main portion 22 in the first direction X may be 1.9 mm, 2.0 mm or 2.1 mm, and the embodiments of the present disclosure are not limited thereto. As long as the dimension D1 of the first main portion 22 in the first direction X is in the range of 1.9 mm to 2.1 mm, the dimension D1 of the first main portion 22 in the first direction X may take any value.

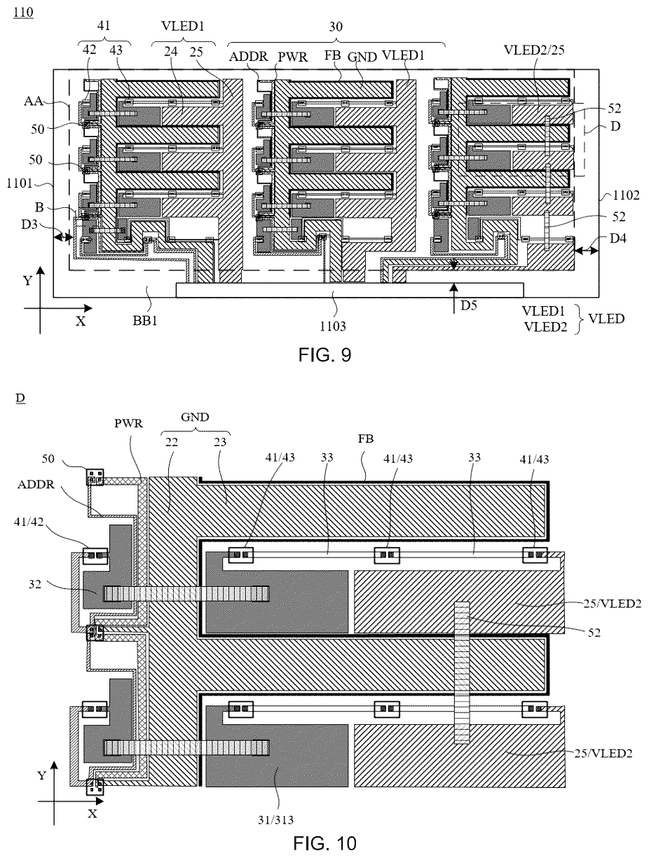

In some embodiments, referring to FIG. 9, at least one of first voltage signal lines VLED included in the plurality of signal line groups 30 is a first target signal line VLED1. The light-emitting substrate 110 includes a plurality of signal line groups 30, each signal line group 30 includes a first voltage signal line VLED. Thus, the light-emitting substrate 110 includes multiple first voltage signal lines VLED, at least one of which is a first target signal line VLED1.

Referring to FIG. 9, the first target signal line VLED1 includes a second main portion 24 and a plurality of second protruding portions 25. The second main portion 24 extends in the second direction Y and is located on a side of the at least one second light-emitting element 43 (all the second light-emitting elements 43 of an element group 40) away from the first light-emitting element 42. The plurality of second protruding portions 25 are located on a side of the second main portion 24 proximate to the ground line GND and are connected to the second main portion 24. The second main portion 24 is also used to connect the plurality of first protruding portions 23 into a whole. The second protruding portions 25 each extend in the first direction X, and are located between two adjacent element groups 40 in the second direction Y. In the embodiments of the present disclosure, the second protruding potions 25 are arranged by utilizing the gap between two adjacent element groups 40, which may increase the area of the first target signal line VLED1 without increasing the area of the substrate 10, thereby reducing the resistance of the first target signal line VLED1. Thus, it is beneficial to reducing the dimension of the second main portion 24 in the first direction X and reducing the dimension of the signal line group 30 in the first direction X. Moreover, it is beneficial to reduce the thickness of the first target signal line VLED1, reduce the amount of etching solution used in the process of forming the ground line GND, so as to reduce the fabricate difficulty and cost of the first target signal line VLED1.

For example, a second light-emitting element 43 farthest from the first light-emitting element 42 may be connected to the second main portion 24. In addition, in the second direction Y, there is a gap between the first connection line 33 and the first protruding portion 23 to avoid signal interference between the first connection line 33 and the first protruding portion 23.

In some embodiments, as shown in FIG. 4, a dimension of the second main portion 24 in the first direction X is denoted as D2, and D2 is in a range of 3.4 mm to 3.7 mm, which is beneficial to increase the area of the second main portion 24, thereby reducing the resistance and thickness of the first voltage signal line VLED. For example, the dimension D2 of the second main portion 24 in the first direction X may be 3.4 mm, 3.5 mm or 3.7 mm, and the embodiments of the present disclosure are not limited thereto. As long as the dimension D2 of the second main portion 24 in the first direction X is in the range of 3.4 mm to 3.7 mm, the dimension D2 of the second main portion 24 in the first direction X may take any value.

In some embodiments, referring to FIGS. 9, 10 and 11, at least one of the first voltage signal lines VLED included in the plurality of signal line groups 30 is a second target signal line VLED2. The second target signal line VLED2 includes a plurality of second protruding portions 25. The plurality of second protruding portions 25 are arranged at intervals in the second direction Y. Each second protruding portion 25 is connected to a corresponding element group 40, and the second protruding portion 25 is located at a side of the element group 40 (connected to the second protruding portion 25) in the second direction Y. The light-emitting substrate 110 further includes a plurality of second bridge portions 52, and the second bridge portion 52 is configured to connect two second protruding portions 25 adjacent in the second direction Y. That is, the second target signal line VLED2 includes a plurality of second protruding portions 25 arranged at intervals in the second direction Y, and the plurality of second protruding portions 25 are electrically connected through the second bridge portions 52. In this way, the space occupied by the signal line group 30 in the first direction X may be further reduced, thereby achieving a narrow bezel of the light-emitting substrate 110.

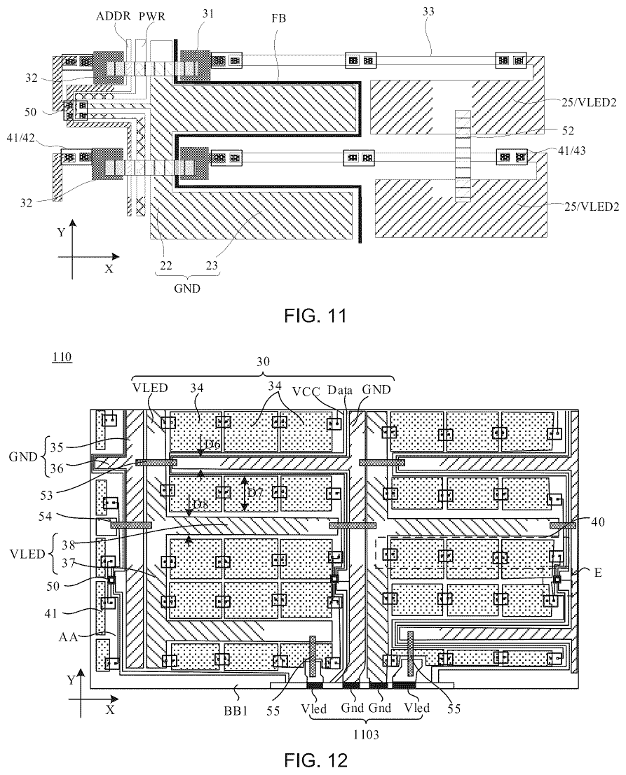

In some embodiments, as shown in FIG. 10, the second protruding portions 25 of the second target signal line VLED2 and the first protruding portions 23 may be arranged side by side in the second direction Y. Alternatively, as shown in FIG. 11, the second protruding portion 25 of the second target signal line VLED2 and the first protruding portion 23 may be arranged side by side in the first direction X.

In some embodiments, as shown in FIG. 9, among the first voltage signal lines VLED included in the plurality of signal line groups 30, the outermost first voltage signal line VLED in the first direction X is the second target signal line VLED2, and the second target signal line VLED2 is adjacent to the frame area BB of the light-emitting substrate 110. That is to say, the first voltage signal line VLED proximate to the frame area BB in the signal line group 30 is the second target signal line VLED2. Thus, it is beneficial to reducing the bezel width of the frame area BB proximate to the second target signal line VLED2, thereby reducing the width of the frame area BB of the light-emitting substrate 110, which is beneficial for the display apparatus 1000 to achieve a narrow bezel.

For example, in the first direction X, the two first voltage signal lines VLED in the two outermost signal line groups 30 are both the outermost first voltage signal lines VLED. However, referring to FIG. 9, in one signal line group 30, the first voltage signal line VLED is located on the right side of the ground line GND. In this case, the signal line of the left signal line group 30 proximate to the frame area BB is the ground line GND, and the signal line of the right signal line group 30 proximate to the frame area BB is the first voltage signal line. Based on this, in the light-emitting substrate 110, the first voltage signal line VLED adjacent to the frame area BB only includes the first voltage signal line VLED of the rightmost signal line group 30. In other words, the first voltage signal line VLED of the rightmost signal line group 30 is the second target signal line VLED2. Thus, it is beneficial to reducing the width of frame area at the right side of the light-emitting substrate 110, and it is beneficial for the display apparatus 1000 to achieve an ultra-narrow bezel.

It can be understood that the embodiments of the present disclosure are not limited to this. In some other embodiments, any one of the plurality of first voltage signal lines VLED may be set as the first target signal line VLED1 or the second target signal line VLED2, which is not specifically limited in the embodiments of the present disclosure, as long as the same technical ideas are adopted.

In some embodiments, referring to FIG. 10, in the second direction Y, a first protruding portion 23 and a second protruding portion 25 are disposed between two adjacent element groups 40. The first protruding portion 23 and the second protruding portion 25 are arranged side by side in the second direction Y. Thus, it is beneficial to increase the dimension of the first protrusion 23 and the second protrusion 25 in the second direction Y, thereby increasing the length of the connecting portion between the first protruding portion 23 and the first main portion 22 and the length of the connecting portion between the second protruding portion 25 and the second main portion 24, which is beneficial to further reduce the resistance of the ground line GND and the first voltage signal line VLED (the first target signal line VLED1).

For example, the dimension of the first protruding portion 23 in the first direction X may be equal to the dimension of the second protruding portion 25 in the first direction X, and the dimension of the first protruding portion 23 in the second direction Y may be equal to the dimension of the second protruding portion 25 in the second direction Y. In this way, it is beneficial to increase the structural consistency of the first protruding portion 23 and the second protruding portion 25, which may increase the structural uniformity of the signal line group 30, thereby reducing the fabricate difficulty of the signal line group 30.

In some embodiments, as shown in FIG. 10, the first connection pattern 31 of the light-emitting substrate 110 is located on a side of the second light-emitting element 43 that is closest to the first light-emitting element 42 in the second direction Y. Between two adjacent element groups 40, for the first protruding portion 23 and the second protruding portion 25, the second protruding portion 25 is closer to the first connection pattern 31. The first connection pattern 31 and the second protruding portion 25 are arranged side by side in the first direction X, which is beneficial to improve the space utilization between two adjacent element groups 40 to maximize the area of the ground line GND and the first voltage signal line VLED.

In some embodiments, in the case where the first protruding portion 23 and the second protruding portion 25 are arranged side by side in the first direction X, referring to FIG. 11, the first connection pattern 31 of the light-emitting substrate 110 is located between the ground line GND and the second light-emitting element 43 closest to the first light-emitting element 42. In this way, it is possible to reduce the dimension of the first connection pattern 31 in the second direction Y to the greatest extent, thereby increasing the wiring space of the first protruding portion 23 to increase the dimension of the first protruding portion 23 in the second direction Y.

In some embodiments, as shown in FIG. 10, in the first direction X, the first connection pattern 31 of the light-emitting substrate 110 and the second protruding portion 25 are arranged side by side in the first direction X. The dimension of the first protruding portion 23 in the first direction X is greater than the dimension of the second protruding portion 25 in the first direction X. In this way, it is possible to utilize the wiring space between two adjacent element groups 40 to the greatest extent, so as to reduce the resistance of the ground line GND and the first voltage signal line VLED.

In some embodiments, referring to FIG. 10, a first protruding portion 23 and a second protruding portion 25 are disposed between two adjacent element groups 40 in the second direction Y. The first protruding portion 23 and the second protruding portion 25 are arranged side by side in the second direction Y, which helps to increase the space utilization between two adjacent element groups 40.

For example, as shown in FIG. 10, the dimension of the third sub-pattern 313 of the first connection pattern 31 in the second direction Y is substantially equal to the dimension of the second protruding portion 25 in the second direction Y, and the dimension of the second protruding portion 25 in the second direction Y may be greater than the dimension of the first protruding portion 23 in the second direction Y. The dimension of the second protruding portion 25 in the first direction X may be greater than the dimension of the third sub-pattern 313 in the first direction X.

It will be understood that, in some other embodiments, in the case where the first voltage signal line VLED of the signal line group 30 is the first target signal line VLED1, one of the first protruding portion 23 and the second protruding portion 25 may be included between two adjacent element groups 40, and in the second direction Y, the arrangement order of the first protruding portions 23 and the second protruding portions 25 and the distribution density of the first protruding portions 23 and the second protruding portions 25 may be selected arbitrarily as long as the same technical ideas are applied. In the case where the first voltage signal line VLED of the signal line group 30 is the second target signal line VLED2, one second protruding portion 25 is included between two adjacent element groups 40 at least, and the distribution density of the first protruding portions 23 may be selected arbitrarily; for example, two, three or four element groups 40 are included between each two adjacent first protruding portions 23.

In some embodiments, as shown in FIG. 11, the signal line group 30 further includes an address signal line ADDR, a power signal line, and a feedback signal line. In the first direction X, the address signal line ADDR, the power signal line PWR, the ground line GND, the feedback signal line FB and the first voltage signal line VLED are arranged in sequence. Portions of the address signal line ADDR and the power signal line PWR are located between the first light-emitting element 42 and the at least one second light-emitting element 43; the feedback signal line FB is located on a side of the ground line GND away from the control chip 50, and extends along a border of the ground line GND away from the control chip 50.

In some embodiments, referring to FIG. 9, the light-emitting substrate 110 includes a first border 1101, a second border 1102 and bonding pins 1103. In the signal line group 30 closest to the first border 1101, the ground line GND closest to the first border 1101 is closer to the first border 1101 than the first voltage signal line VLED closest to the first border 1101. The distance between the first border 1101 and the signal line group 30 is denoted as D3, and D3 is in a range of 2.0 mm to 2.3 mm. For example, the distance D3 between the first border 1101 and the signal line group 30 is 2.0 mm, 2.2 mm or 2.3 mm, and the embodiments of the present disclosure do not limited thereto.

The first border 1101 and the second border 1102 are opposite to each other in the first direction X. In the signal line group 30 closest to the second border 1102, the first voltage signal line VLED closest to the second border 1102 is closer to the second border 1102 than the ground line GND closest to the second border 1102. The distance between the second border 1102 and the signal line group 30 is denoted as D4, and D4 is in a range of 2.0 mm to 2.3 mm. For example, the distance D4 between the second border 1102 and the signal line group 30 is 2.0 mm, 2.1 mm or 2.3 mm, which is not specifically limited in the embodiments of the present disclosure.

The distance D3 between the first border 1101 and the signal line group 30 and the distance D4 between the second border 1102 and the signal line group 30 may be equal or unequal, which is not limited in the embodiments of the present disclosure. For example, the distance D3 between the first border 1101 and the signal line group 30 is equal to the distance D4 between the second border 1102 and the signal line group 30. In this way, the widths of the frame area at two opposite sides in the first direction X of the light-emitting substrate 110 are equal, which is conducive to the symmetry for the bezel width of the display apparatus 1000.

In the second direction, the minimum distance between the bonding pins 1103 and the signal line group 30 is denoted as D5, and D5 is in a range of 1.3 mm to 1.6 mm. For example, the minimum distance D5 between the bonding pins 1103 and the signal line group 30 is 1.3 mm, 1.45 mm, or 1.6 mm, etc., which is not specifically limited in the embodiments of the present disclosure.

In some other embodiments, in a case where the plurality of light-emitting elements 41 of the element group 40 are disposed between the ground line GND and the first voltage signal line VLED, referring to FIGS. 12 and 13, the light-emitting substrate 110 further includes second connection lines 34. The second connection line 34 is located between two adjacent light-emitting elements 41 of the element group 40, and is configured to connect the two adjacent light-emitting elements 41. A dimension of the second connection line 34 in the second direction Y is greater than the dimension of the light-emitting element 41 in the second direction Y. The distance between two adjacent second connection lines 34 in the second direction Y is less than the dimension of the second connection line 34 in the second direction. In the embodiments of the present disclosure, the gap between two adjacent element groups 40 is utilized to form the second connection line 34 with a great area, which is beneficial to reducing the resistance of the second connection line 34, accelerating the heat dissipation efficiency of the second connection line 34; and in addition, it is beneficial to reducing the thickness of the signal line group 30, thereby reducing the amount of etching solution used during the formation of the signal line group 30.

In some embodiments, referring to FIG. 12, the ground line GND includes a third main portion 35 and at least one third protruding portion 36. The third main portion 35 extends in the second direction Y. The third protruding portion(s) 36 are located on a side of the third main portion 35 proximate to the first voltage signal line VLED and connected to the third main portion 35. The third protruding portion 36 extends in the first direction X and is located between two adjacent element groups 40 in the second direction Y.

For example, a dimension of the third protruding portion 36 in the first direction X is greater than a dimension of the second connection line 34 in the first direction X, so that the dimension of the third protruding portion 36 in the first direction X may be increased to the greatest extent, so as to reduce the span of the third bridge portion 53. A dimension of the third protruding portion 36 in the second direction Y is less than a dimension of the second connection line 34 in the second direction Y, which is beneficial to increase the area of the second connection line 34 to reduce the resistance of the second connection line 34.

The first voltage signal line VLED includes a fourth main portion 37 and at least one fourth protruding portion 38. The fourth protruding portion 38 extends in the second direction Y. The at least one fourth protruding portion 38 is located on a side of the fourth main portion 37 proximate to the ground line GND and is connected to the fourth main portion 37. The fourth protruding portion 38 extends in the first direction X and is located between two adjacent element groups 40.

The light-emitting substrate 110 further includes third bridge portions 53 and fourth bridge portions 54. An end of the third bridge portion 53 is electrically connected to an end of the third protruding portion 36 away from the third main portion 35, and the other end of the third bridge portion 53 is electrically connected to the ground line GND of the adjacent control chip 30. That is, the third bridge portion 53 may electrically connect two ground lines GND of two adjacent signal line groups 30, so that the plurality of the ground lines GND of the plurality of signal line groups 30 are connected to one another to constitute a mesh structure, thereby reducing the resistance of the ground line GND.

An end of the fourth bridge portion 54 is electrically connected to an end of the fourth protruding portion 38 away from the fourth main portion 37, and the other end of the fourth protruding portion 38 is electrically connected to the first voltage signal line VLED of the adjacent signal line group 30. That is, the fourth bridge portion 54 may electrically connect two first voltage signal lines VLED of two adjacent signal line groups 30, so that the plurality of first voltage signal lines VLED of the plurality of signal line groups 30 are connected to one another to constitute a mesh structure, thereby reducing the resistance of the first voltage signal line VLED.

In some embodiments, at least one element group 40 is disposed between the third protruding portion 36 and the fourth protruding portion 38 that are adjacent to each other in the second direction Y. That is, at most one of the third protruding portion 36 and the fourth protruding portion 38 is included between two adjacent element groups 40 in the second direction Y. In this way, more wiring space may be reserved between two adjacent element groups 40 for arranging the second connection line 34, which is beneficial to increase the dimension of the second connection line 34 in the second direction Y, thereby reducing the resistance of the second connection line 34.

For example, referring to FIG. 12, in the second direction Y, a dimension D6 of the third protruding portion 36 is less than a dimension D7 of the second connection line 34, and a dimension D8 of the fourth protruding portion 38 is less than the dimension D7 of the second connection line 34.

In some embodiments, referring to FIG. 12, the light-emitting substrate 110 has a device area AA and a bonding area BB1 that are arranged side by side in the second direction Y, and the light-emitting elements 41 of the plurality of element groups 40 are arranged in the device area AA. The light-emitting substrate 110 further includes bonding pins 1103 and fifth bridge portions 55. The bonding pins 1103 include a first voltage signal pin Vled for transmitting a first voltage signal and a ground pin Gnd. The fifth bridge portion 55 is configured to connect the first voltage signal line VLED and the first voltage signal pin Vled. The ground line GND is connected to the ground pin Gnd.

In some embodiments, referring to FIGS. 12 and 13, the signal line group 30 further includes an address signal line ADDR, a data signal line Data, and a power signal line PWR. In the first direction, the first voltage signal line VLED, the power signal line PWR, the data signal line Data, the address signal line ADDR and the ground line GND are arranged in sequence.

The above are only specific embodiments of the present disclosure, but the scope of protection of the present disclosure is not limited thereto, and any person skilled in the art may conceive of variations or replacements within the technical scope of the present disclosure, which shall fall within the protection scope of the present disclosure. Therefore, the protection scope of the present disclosure should be determined by the protection scope of the claims.

1. A light-emitting substrate, comprising:
a substrate;
a plurality of signal line groups disposed on the substrate, wherein the plurality of signal line groups are arranged in a first direction, and each signal line group includes a plurality of signal lines arranged in the first direction;
a plurality of columns of element groups arranged in the first direction, wherein each column of element groups includes a plurality of element groups arranged at intervals in a second direction, a column of element groups is electrically connected to a part of signal lines of a signal line group, and each element group includes a plurality of light-emitting elements arranged at intervals in the first direction and electrically connected in sequence; the first direction intersects the second direction;
a plurality of columns of control chips arranged in the first direction, wherein each column of control chips includes a plurality of control chips arranged at intervals in the second direction, a column of control chips is arranged on a side of the column of element groups and is electrically connected to the column of element groups and a part of signal lines of the signal line group.

2. The light-emitting substrate according to claim 1, wherein
the plurality of light-emitting elements of the element group comprises a first light-emitting element and at least one second light-emitting element; the first light-emitting element is located at an end of the element group in the first direction;
the signal line group includes a ground line and a first voltage signal line, the ground line is located between the first light-emitting element and the at least one second light-emitting element, and the first voltage signal line is located on a side of the at least one second light-emitting element away from the first light-emitting element; and
the control chip is disposed on a side of the first light-emitting element in the second direction.

3. The light-emitting substrate according to claim 2, further comprising a first bridge portion, wherein the plurality of light-emitting elements of the element group include a plurality of second light-emitting element, the first bridge portion is configured to connect the first light-emitting element and a second light-emitting element that is closest to the first light-emitting element.

4. The light-emitting substrate according to claim 3, wherein the element group includes a plurality of second light-emitting elements;
the signal line group further includes a first connection line, the first connection line is disposed between two adjacent second light-emitting elements and is configured to connect the two adjacent second light-emitting elements;
the light-emitting substrate further comprises a first connection pattern electrically connected to the second light-emitting element that is closest to the first light-emitting element and electrically connected to the first bridge portion;
wherein a dimension of the connection pattern in the second direction is greater than a dimension of the connection line in the second direction.

5. The light-emitting substrate according to claim 4, wherein a resistivity of the first bridge portion is less than a resistivity of the first connection line.

6. The light-emitting substrate according to claim 4, wherein the signal line group further includes a second connection pattern electrically connected to the first light-emitting element and the first bridge portion;
wherein a dimension of the second connection pattern in the second direction is greater than a dimension of the first connection line in the second direction.

7. The light-emitting substrate according to claim 6, wherein the second connection line is located on a side of the first light-emitting element in the second direction or located between the first light-emitting element and the ground line.

8. The light-emitting substrate according to claim 2, wherein the ground line includes:
a first main portion extending in the second direction and located between the first light-emitting element and the at least one second light-emitting element; and
a plurality of first protruding portions located on a side of the first main portion proximate to the at least one second light-emitting element and connected to the first main portion;
wherein a first protruding portion extends in the first direction and is located between two adjacent element groups in the second direction.

9. The light-emitting substrate according to claim 8, wherein at least one of all first voltage signal lines included in the plurality of signal line groups is a first target signal line, and the first target signal line includes:
a second main portion extending in the second direction and located on a side of the at least one second light-emitting element away from the first light-emitting element; and
a plurality of second protruding portions located on a side of the second main portion proximate to the ground line and connected to the second main portion; wherein a second protruding portion extends in the first direction and is located between the two adjacent element groups in the second direction.

10. The light-emitting substrate according to claim 8, wherein at least one of all first voltage signal lines included in the plurality of signal line groups is a second target signal line, and the second target signal line includes:
a plurality of second protruding portions arranged at intervals in the second direction; each second protruding portion is connected to a corresponding element group, and the second protrusion is located on a side of the element group in the second direction;
the light-emitting substrate further comprises a plurality of second bridge portions, and a second bridge portion is configured to connect two second protruding portions adjacent in the second direction.

11. The light-emitting substrate according to claim 10, wherein among the first voltage signal lines included in the plurality of signal line groups, an outermost first voltage signal line in the first direction is the second target signal line, and the second target signal line is adjacent to a frame area of the light-emitting substrate.

12. The light-emitting substrate according to claim 9, wherein
the first protruding portion and the second protruding portion are arranged side by side in the first direction; or
the first protruding portion and the second protruding portion are arranged side by side in the first direction, and the light-emitting substrate further comprises a first connection pattern electrically connected to a second light-emitting element that is closer to the first light-emitting element and located between the ground line and the second light-emitting element that is closest to the first light-emitting element.

13. (canceled)

14. The light-emitting substrate according to claim 9, wherein
the first protruding portion and the second protruding portion are arranged side by side in the second direction.

15. The light-emitting substrate according to claim 14, wherein the light-emitting substrate further comprises a first connection pattern electrically connected to a second light-emitting element that is closest to the first light-emitting element and located on a side of the second light-emitting element that is closest to the first light-emitting element in the second direction;
the light-emitting substrate further comprises a first connection pattern electrically connected to a second light-emitting element that is closest to the first light-emitting element and located on a side of the second light-emitting element that is closest to the first light-emitting element in the second direction; wherein the first connection pattern and the second protruding portion of the light-emitting substrate are arranged side by side in the first direction, and a dimension of the first protruding portion in the first direction is greater than a dimension of a second protruding portion in the first direction.

16. (canceled)

17. (canceled)

18. The light-emitting substrate according to claim 2, the signal line group further includes an address signal line, a power signal line, and a feedback signal line; wherein
in the first direction, the address signal line, the power signal line, the ground line, the feedback signal line and the first voltage signal line are arranged in sequence; and
a portion of the address signal line and a portion of the power signal line are located between the first light-emitting element and the at least one second light-emitting element, and the feedback signal line is located on a side of the ground line away from the control chip and extends along a border of the ground line away from the control chip.

19. (canceled)

20. (canceled)

21. The light-emitting substrate according to claim 1, wherein
the signal line group includes a ground line and a first voltage signal line; and the plurality of light-emitting elements of the element group are arranged between the ground line and the first voltage signal line; or
the signal line group includes a ground line and a first voltage signal line; and the plurality of light-emitting elements of the element group are arranged between the ground line and the first voltage signal line; and the light-emitting substrate further comprises: second connection lines, a second connection line being located between two adjacent light-emitting elements of the element group and configured to connect the two adjacent light-emitting elements; wherein a dimension of the second connection line in the second direction is greater than a dimension of the light-emitting element in the second direction; and a distance between two adjacent second connection lines in the second direction is less than the dimension of the second connection line in the second direction.

22. The light-emitting substrate according to claim 21, wherein
the ground line includes:
a third main portion extending in the second direction; and
at least one third protruding portion located on a side of the third main portion proximate to the first voltage signal line and connected to the third main portion; wherein a third protruding portion extends in the first direction and is located between two adjacent element groups in the second direction;
the first voltage signal line includes:
a fourth main portion extending in the second direction; and
at least one fourth protruding portion located on a side of the fourth main portion proximate to the ground line and connected to the fourth main portion; wherein a fourth protruding portion extends in the first direction and is located between another two adjacent element groups in the second direction; and
the light-emitting substrate further comprises:
a third bridging portion, wherein an end of third bridging portion is electrically connected to an end of the third protruding portion away from the third main portion, and another end of third bridging portion is electrically connected to a ground line of an adjacent signal line group; and
a fourth bridge portion, wherein an end of the fourth bridge portion is electrically connected to an end of the fourth protruding portion away from the fourth main portion, and another end of the fourth protruding portion is electrically connected to a first voltage signal line of another adjacent signal line group.

23. The light-emitting substrate according to claim 22, wherein at least one element group is arranged between a third protruding portion and a fourth protruding portion that are adjacent to each other in the second direction; in the second direction, a dimension of the third protruding portion is less than the dimension of the second connection line, and a dimension of the fourth protruding portion is less than the dimension of the second connection line.

24. (canceled)

25. The light-emitting substrate according to claim 21, wherein the signal line group further includes an address signal line, a data signal line and a power signal line; in the first direction, the first voltage signal line, the power signal line, the data signal line, the address signal line and the ground line are arranged in sequence.

26. A display apparatus, comprising:
the light-emitting substrate according to claim 1; and
a display panel, wherein the light-emitting substrate is located on a non-display surface of the display panel.
